(19) United States
(12) Patent Application Publication
(10) Pub. No.: US 2014/0224019 A1
(43) Pub. Date: Aug. 14, 2014

(54) PIEZOELECTRIC SENSORS AND SENSOR ARRAYS FOR THE MEASUREMENT OF WAVE PARAMETERS IN A FLUID, AND METHOD OF MANUFACTURING THEREFOR

(71) Applicants: Martin Brouillette, Sherbrooke (CA); Gholamreza Mirshekari, Sherbrooke (CA)

(72) Inventors: Martin Brouillette, Sherbrooke (CA); Gholamreza Mirshekari, Sherbrooke (CA)

(73) Assignee: SOCPRA SCIENCES ET GENIE S.E.C., Sherbrooke, QC (CA)

(21) Appl. No.: 14/234,170

(22) PCT Filed: Aug. 6, 2012
(86) PCT No.: PCT/CA2012/000736

§ 371 Date: Apr. 10, 2014

Related U.S. Application Data
(60) Provisional application No. 61/521,022, filed on Aug. 8, 2011.

(51) Int. Cl. G01L 9/08; H01L 41/332; G01H 11/08

(52) U.S. Cl. CPC G01L 9/08; G01H 11/08; H01L 41/332
USPC 73/579; 73/754; 73/662; 438/53

(57) ABSTRACT

The present disclosure relates to piezoelectric sensors and piezoelectric sensor arrays, to methods of manufacturing therefor, and to a method of measuring characteristics of a mechanical wave using a piezoelectric sensor array. A piezoelectric sensor is formed of a silicon substrate on which an electrical barrier is added. A patterned bottom electrode layer is added on top of the electrical barrier. A patterned bottom electrode layer is added on top of the electrical barrier. A piezoelectric layer and then a patterned top electrode layer are added on top of the electrical barrier.

### TECHNICAL FIELD

The present disclosure generally relates to pressure sensors. More specifically, but not exclusively, the present disclosure is concerned with piezoelectric pressure sensors and with an array of piezoelectric pressure sensors for wave parameters measurement, and with methods for producing piezoelectric pressure sensors.

### BACKGROUND

The advance in microfabrication techniques makes it possible to produce very accurate and versatile sensors used in a variety of systems involving mechanical, electrical, optical and biological sensing. A major group of mechanical sensing devices use the piezoelectric effect to obtain high speed detection of a mechanical displacement, a pressure or a force. Because of their fast responses, these types of sensors are very popular in applications involving wave propagation, either shock waves or acoustic waves. Using the proper sensors and signal conditioning systems, it is possible to provide an accurate history of pressure variation in a certain location, resulted from passage of the waves. However, to obtain a complete picture of wave propagation in the medium it is necessary to probe the medium in different locations, so that the direction and the speed of the wave could be measured, in addition to its amplitude time history.

There are many applications for simple devices that could measure the local velocity vector of a mechanical wave. Shock tubes have been known in the art of fluid mechanics for quite some time. Shock tubes may be used in the study of unsteady high speed flows. To acquire practical information on the speed and propagation of a wave in a shock tube, a number of sensors are typically installed along the length of the shock tube in such a manner as to detect change in at least one physical property of a gas contained in that shock tube.

Sensing the speed of a wave may, in theory, be made using, for example, two pressure transducers installed along a shock tube. Measuring the time taken by the wave to travel between the two transducers and knowing the distance between them allows for the computation of the average wave speed over this distance. The wave velocity may have fluctuated when travelling from one transducer to the next, therefore such a setup allows for measuring the average speed.

Furthermore, measuring the direction of propagation of a wave may, in theory, be made using more than two sensors, wherein this plurality of sensors is not located on a straight line. However, such a simple setup may render the measurements inaccurate. This is because the speed and direction of a pressure wave jointly define a velocity vector whose properties may depend on the position of the wave. To obtain an accurate measurement of the local wave velocity vector therefore requires the plurality of sensors to be in close proximity. This is difficult to achieve with current commercial pressure sensors which are packaged individually and which each occupies a fairly large surface of many square millimeters.

The same situation may take place in components of turbomachines, such as fans, compressors and turbines. Many flow phenomena in gas turbines are unsteady, meaning that the flow properties vary in time at a certain fixed location, leading to wave propagating in various directions. For example, some or all blades within a compressor may stall and the pressure at a given location may vary in time. To identify the amplitude, speed and direction of stall waves in such a situation would require the use of many pressure sensors in close proximity, a configuration difficult to achieve in practice due to the relatively large size of actual pressure sensors and the limited space available in typical turbomachines.

Another situation takes place in microdevices where the space available for measuring the speed of waves is severely limited. Microscale shock tubes have been introduced for this purpose. Such shock tubes may have cross sections of the order of a few micrometers. Obviously, measurements of physical properties of gas taking place in such small scales cause important difficulties, and the size of sensors cannot exceed the size of the channel of the microscale shock tube. Moreover, in operation, these sensors need to be put in direct contact with the flow of gas and have a reaction time sufficiently fast to detect gaseous pressure changes occurring at nanosecond scales.

Conventional pressure sensors require the presence of a mechanical element, such as a membrane, having a shape that may be altered under pressure in a manner that the shape alteration may be measured. Miniaturization of the sensors implies a very small and very thin membrane, difficult to fabricate, whose shape alteration that may only be measured using technologically complex methods, such as with an atomic force microscope, for example.

There therefore exists a need for a method for fabricating sensors that are simple to operate and yet are sufficiently small that an array of them may be packaged in a small area and volume.

### SUMMARY

According to the present disclosure, there is provided a method for manufacturing a piezoelectric sensor. An electrical barrier is formed on top of a silicon substrate. A bottom electrode layer defining a bottom positive electrode section and a bottom negative electrode section is deposited on top of the electrical barrier. A piezoelectric layer is deposited on top of the bottom electrode layer. A positive electrode connection area and a negative electrode connection area are etched, through the piezoelectric layer. A top electrode layer is deposited on top of the piezoelectric layer. The top electrode layer is making contact with the bottom electrode layer through the positive and negative electrode connection areas and defines a upper positive electrode section and a upper negative electrode section. A sensing area is created, in the piezoelectric layer, in an area of overlap between the upper positive electrode section and the bottom negative electrode section or between the upper negative electrode section and the bottom positive electrode section.

According to the present disclosure, there is also provided a piezoelectric sensor comprising a silicon substrate, an electrical barrier on top of the silicon substrate, a bottom electrode layer on top of the electrical barrier, a piezoelectric layer on top of the bottom electrode layer, and a top electrode layer on top of the piezoelectric layer. The bottom electrode layer defines a bottom positive electrode section and a bottom negative electrode section. The piezoelectric layer defines a positive electrode connection area and a negative electrode connection area. The top electrode layer makes contact with the bottom electrode layer through the positive and negative electrode connection areas and defines a upper positive electrode section and a upper negative electrode section. A sensing area is defined, in the piezoelectric layer, in an area of overlap between the upper positive electrode section and the bottom negative electrode section or between the upper negative electrode section and the bottom positive electrode section.

According to the present disclosure, there is also provided a method of measuring an amplitude, a speed and a direction of propagation of a shock wave in a shock tube. A piezoelectric sensor array comprising a plurality of piezoelectric sensors disposed in a pre-defined configuration is attached to the shock tube. The piezoelectric sensor array is connected to a signal analysis device. The shock wave is initiated in the shock tube. The signal analysis device detects an arrival time of the shock wave at each of the plurality of piezoelectric sensors.

The present disclosure further relates to a smart pressure sensor array comprising a plurality of sensors packaged in close proximity in the sensor array, and one or more wired connections for connecting the sensors to a data acquisition system. The sensor array provides the data acquisition system with pressure time histories at an individual location of each sensor of the array.

### BRIEF DESCRIPTION OF THE DRAWINGS

In the appended drawings:

FIG. 1 is a schematic diagram illustrating the operational difference between a single conventional pressure sensor and a smart array of pressure sensors;

FIG. 2 is a top plan, schematic view of an example of circular sensor array comprising eight (8) sensors;

FIG. 3 is a graph representing measured times versus an angle of each sensor of the circular sensor array of FIG. 2;

FIG. 4 is a top plan, schematic view of an example of cross-shaped sensor array comprising five (5) sensors;

FIG. 5 is a sequence of cross-sectional elevation views showing examples of operations that may be used in the production of a sensor;

FIG. 6 illustrates a top plan view and a cross sectional elevation view of a piezoelectric pressure sensor, produced using the method of FIG. 5;

FIG. 7 is a top plan view of a ring sensor array comprising eight (8) sensors;

FIG. 8 is a perspective view of an example of packaging for supporting the ring-shaped array of eight (8) piezoelectric sensors of FIG. 7;

FIG. 9 is a sequence of cross-sectional elevation views showing alternate examples of operations that may be used in the production of the sensor array for advanced packaging;

FIG. 10 is a close-up, cross-sectional elevation view of the sensor array produced using the operations of FIG. 9;

FIG. 11 is an example of a packaging method for the sensors arrays fabricated using the process shown in FIG. 9;

FIG. 12 is a flow chart of examples of operations of a method of simultaneously measuring an amplitude time history, a speed and a direction of propagation of a shock wave or mechanical wave in flow; and

FIG. 13 is an elevation view of an example of set up for measuring the speed and direction of propagation of a wave.

### DETAILED DESCRIPTION

The foregoing and other objects, advantages and features of the present disclosure will become more apparent upon reading of the following non-restrictive description of illustrative embodiments thereof, given by way of example only with reference to the accompanying drawings.

Generally stated, sensors and sensor arrays described herein may be applied to measuring a physical property of a fluid such as a gas or liquid, for example pressure of the gas in a shock tube. Many pressure sensors may be fabricated and packaged into a device comprising an array of sensors occupying no more space than a single conventional pressure sensor. A possible application of the arrays of theses sensors with particular geometries comprises measuring the amplitude, speed and the direction of propagation of waves in a fluid. Simultaneous local measurement of wave amplitude, speed and direction with great spatial and temporal resolutions may be obtained with high accuracy. Another possible application is the measurement of wave speed and wave propagation direction in turbomachinery such as fans, compressors and turbines. A non-limitative example of implementation is an array of sensors comprising five (5) to eight (8) sensors, the sensors being positioned in a pre-defined configuration or geometry, for example a circular geometry or a cross-shaped configuration.

Piezoelectric direct sensing pressure sensor arrays suitable for various applications have been fabricated and tested. The sensor arrays exhibit small size, for each sensor, of the order of a few microns, and fast time response, with a natural frequency which may exceed 1 GHz. Fabrication of such piezoelectric sensors involves in part processing of piezoelectric material such as, for example, Lead Zirconate Titanate (PZT) thin films.

A circular configuration of the sensor arrays provides a good resolution in the measurement of the direction of propagation of the wave. A circular array of eight (8) sensors is sufficient to obtain a small deviation between theoretical expectations and actual laboratory results. For very high speed applications, a simpler, cross-shaped array actually requires less post-processing calculation power.

While the present disclosure relates mainly to applications of the sensor array to large scale and microscale shock tubes as well as turbomachines, those of ordinary skill in the art will appreciate that the sensor array may also be used in many other applications where small sensing devices are used.

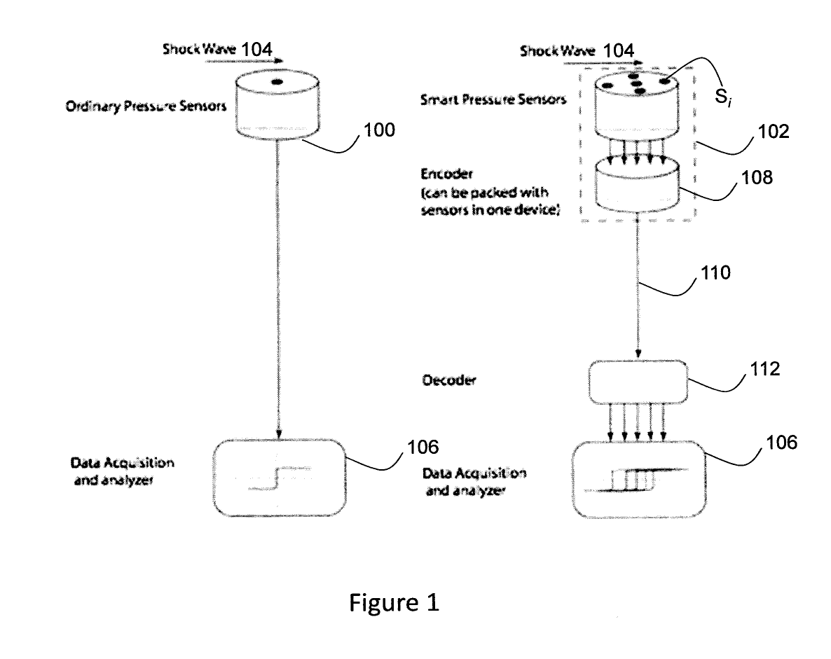

Turning now to drawings, FIG. 1 is a schematic diagram illustrating the operational difference between a single conventional pressure sensor and a smart array of pressure sensors. The Figure shows the general idea and compares this smart sensor concept with conventional sensors. For example, a single conventional pressure sensor 100 measures the pressure time history at the sensor location, which provides the amplitude of a shock wave 104 in time but no information about the velocity and the direction of the wave propagation.

A smart pressure sensor array 102 uses a plurality of sensors Sᵢ packaged in the same device 102 in close proximity to provide the pressure time histories at each individual sensor location. By simultaneously analyzing the pressure time histories at different positions it is possible to very accurately calculate the speed and also the direction of propagation of the wave 104. The sensors Sᵢ may be wired individually to a data acquisition and analysis system 106 or the signals from different sensors Sᵢ of the array 102 may be coded at an encoder 108 and merged into one signal that may be transmitted with a single wire 110 and then separated by a decoder 112 and supplied to the data acquisition and analysis system 106, as shown in FIG. 1.

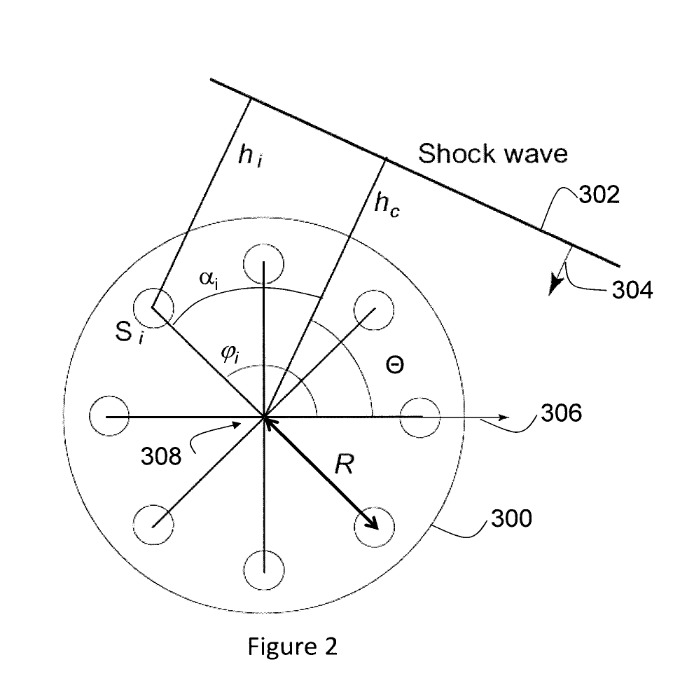

FIG. 2 is a top plan, schematic view of an example of circular sensor array comprising eight (8) sensors. FIG. 2 illustrates a circular array 300 comprising eight (8) sensors Sᵢ, which is exposed to the passage of a shock wave 302, or mechanical wave. In FIG. 2, R is a radius of a circle on which the sensors Sᵢ are located, θ is an angle between a direction of propagation 304 of the shock wave 302 and a reference direction 306 on the circular sensor array 300, and φᵢ is an angle between the orientation of every sensor Sᵢ, relative to a center 308 of the circular sensor array 300 and the reference direction 306. In an embodiment of the circular sensor array 300, R=2800 μm, the eight (8) sensors Sᵢ are distributed evenly around a circle of radius R, yielding an angle of 45 degrees between each pair of adjacent sensors Sᵢ relative to the center 308. At a certain time chosen to be a measurement time reference (for example the trigger time of oscilloscopes used for the measurement), the shock wave 302 is at a distance h_{c} from the center 308 and at a distance hᵢ from each sensor Sᵢ. For this situation, the distance hᵢ may be calculated using equation (1):

hᵢ=h_{c}−R cos(φᵢ−θ) (1)

Assuming a constant local speed μₛ of the shock wave 302, dividing equation (1) by the speed of the shock wave, an arrival time of the shock wave 302 on each sensor Sᵢ may be calculated using equation (2):

$${t}_{i} = {t}_{c} - \frac{R}{{u}_{s}} cos ( {Φ}_{i} - Θ ) \qquad ( 2 )$$

In equation (2), t_{c} and tᵢ designate times of arrival of the shock wave 302 at the center 308 of the circular sensor array 300 and at each sensor Sᵢ, respectively. Equation (2) is of particular interest in that it relates the time of arrival tᵢ of the shock wave on each sensor (which is a measurand) and allows postprocessing calculations for obtaining the speed and the direction of propagation of the shock wave.

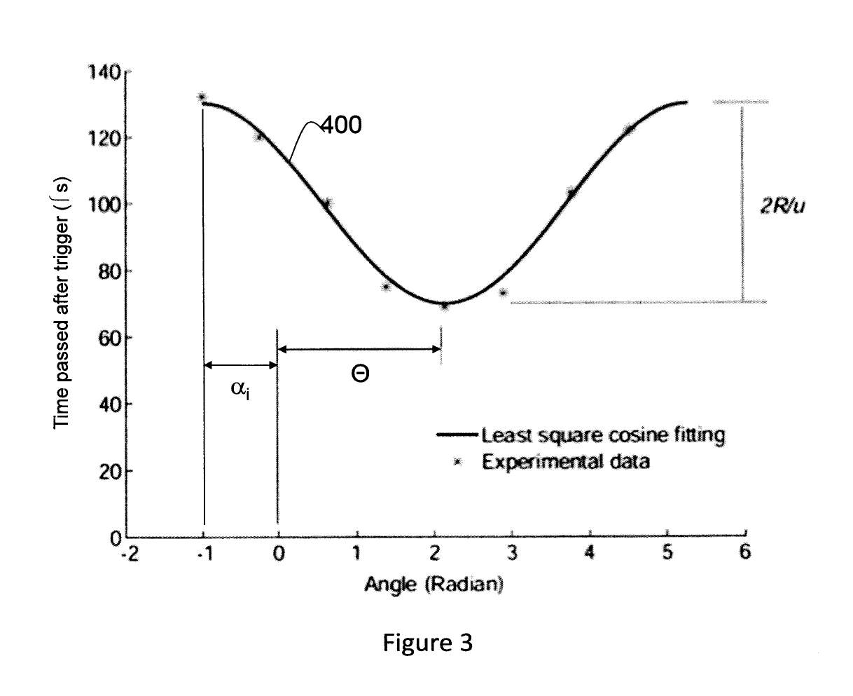

FIG. 3 is a graph representing measured times of arrival of the shock wave on each sensor versus an angle of each sensor of the circular sensor array of FIG. 2. An angle αᵢ is defined between a direction of propagation and an orientation of each sensor Sᵢ relative to the center 308 of the circular sensor array 300. Theoretically, these points are on a cosine curve 400 having an amplitude R/μ, where μ is the speed of the shock wave or mechanical wave, and a phase shift of curve 400 relative to the reference direction 306 is the angle θ. It should be observed that there is some rotation of the circular sensor array 300 relative to the shock wave 302 between FIGS. 2 and 3; consequently, the value of the angle θ differs between these two Figures.

Therefore, to find the speed and the direction of propagation of the shock wave, a cosine curve may be fitted to the data as illustrated in FIG. 3. The proper cosine function may be found using nonlinear least square method. As shown on FIG. 3, experimental data obtained through measurement of the circular sensor array 300 of FIG. 3 allow for the accurate determination of wave speed and direction.

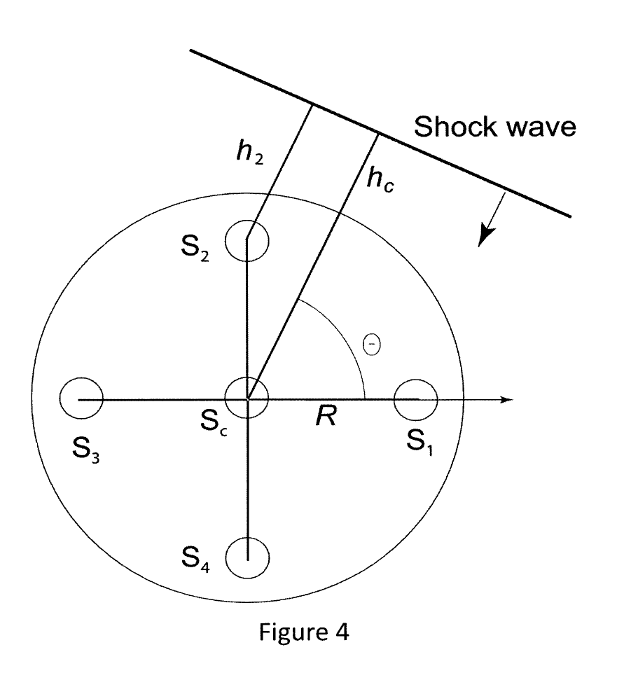

Some other geometries, for example a cross shape array of 5 sensors, are also possible. FIG. 4 is a top plan, schematic view of an example of cross-shaped sensor array comprising five (5) sensors. The cross-shaped geometry may make the postprocessing calculation easier and more accurate. For this geometry we have:

t₂=t_{c}−(R/μₛ)sin θ (3)

where t_{c} and t₂ are the time of arrival of the shock wave or mechanical wave to the center of the device and the outer sensor S₂, respectively. Equation 3 again relates the arrival time of the shock wave on each sensor (which is a measurand) to the speed and the direction of the shock wave. Doing the same calculation for all the outer sensors S₁, S₂, S₃ and S₄ we have:

t_{c}−t₁=(R/μₛ)cos θ (4a)

t_{c}−t₂=(R/μₛ)sin θ (4b)

t_{c}−t₃=−(R/μₛ)cos θ (4c)

t_{c}−t₄=−(R/μₛ)sin θ (4d)

and therefore the wave direction θ may be obtained from:

$$\begin{matrix}tan θ = ( {t}_{c} - {t}_{2} ) / ( {t}_{c} - {t}_{1} ) \\ = ( {t}_{c} - {t}_{4} ) / ( {t}_{c} - {t}_{3} ) \\ = ( {t}_{4} - {t}_{c} ) / ( {t}_{c} - {t}_{1} ) \\ = ( {t}_{2} - {t}_{c} ) / ( {t}_{c} - {t}_{3} )\end{matrix} \qquad ( 5 )$$

and the wave speed obtained from:

$$\begin{matrix}{μ}_{s} = ( R cos θ ) / ( {t}_{c} - {t}_{1} ) \\ = ( R sin θ ) / ( {t}_{c} - {t}_{2} ) \\ = ( R cos θ ) / ( {t}_{3} - {t}_{c} ) \\ = ( R sin θ ) / ( {t}_{4} - {t}_{c} )\end{matrix} \qquad ( 6 )$$

Since the equations (5) and (6) are over-determined and there are four (4) different equations for each unknown θ and μₛ, these two sets of equations may be used to obtain the final result by averaging over the computed values or used to eliminate spurious or faulty measurements.

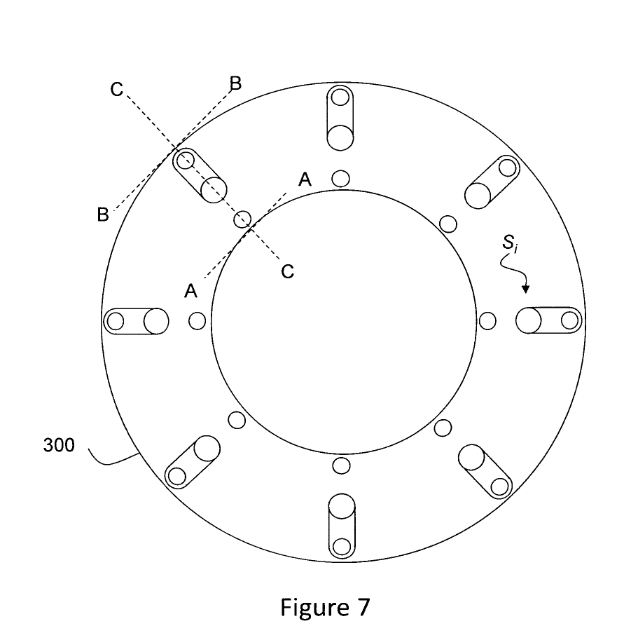

As a non-limitative example, the circular sensor array 300 of FIG. 2 may take, as illustrated in FIG. 7, which is introduced hereinbelow, the form of a ring-shaped array 300 of eight (8) sensors Sᵢ, equally distributed along the ring of the array. One of the sensors Sᵢ is delimited by the lines A-A and B-B in FIG. 7.

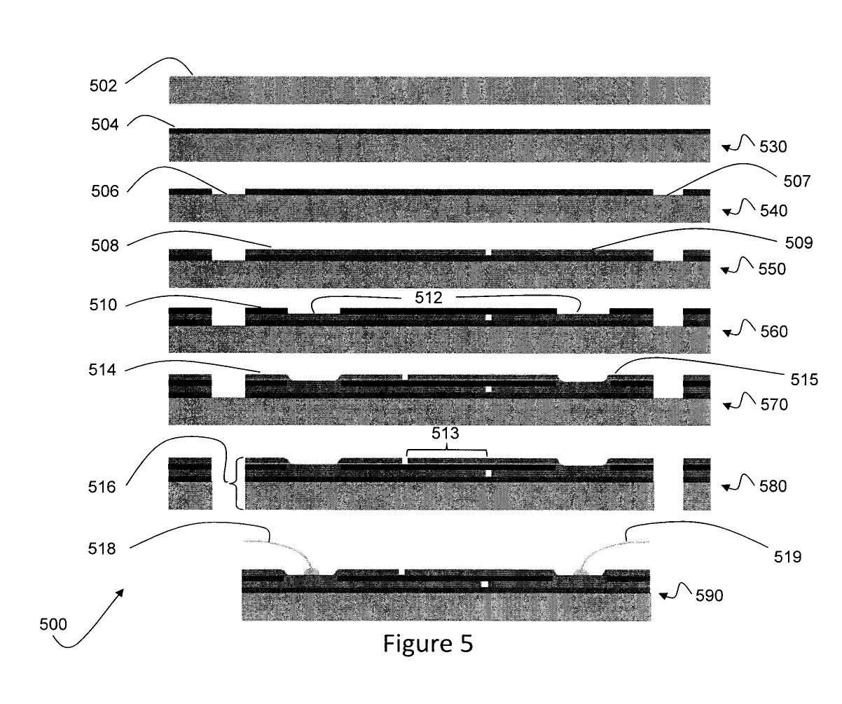

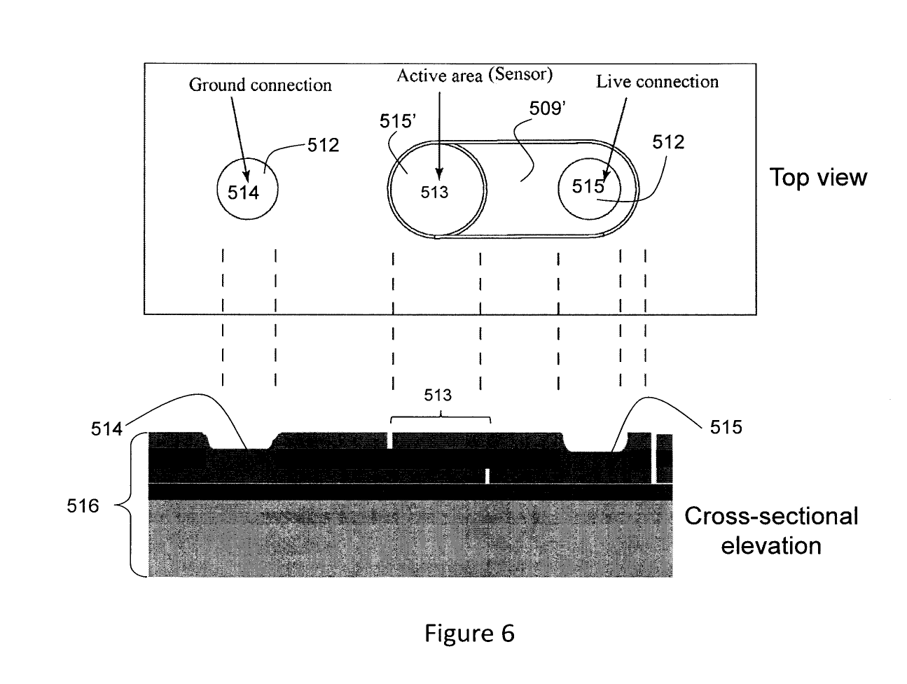

An example of a method of fabrication for the sensor Sᵢ delimited by the lines A-A and B-B of FIG. 7, which is introduced hereinbelow, will now be described with references to FIGS. 5 and 6.

FIG. 5 is a sequence of cross-sectional elevation views showing examples of operations that may be used in the production of a sensor. In this illustrative embodiment, the sensor Sᵢ is a pressure piezoelectric sensor. More specifically, the sequence of elevation views of FIG. 5 show a cross section of the sensor Sᵢ taken along line C-C of FIG. 7, between lines A-A and B-B.

The cross-sectional elevation views of FIG. 5 schematically shows operations of a microfabrication procedure 500, wherein each operation depicts addition or removal of layered components on a 380 micron thick silicon substrate 502. As a non-limitative example, the silicon substrate 502 is a single side polished (SSP) substrate, with a [100] Miller index crystal orientation.

A first operation 530 comprises a thermal oxidation of the polished face of the substrate 502. This operation 530 produces an approximately 600 nanometers (nm) thick oxide layer 504 acting as an electrical barrier on top of which other layers will subsequently be added.

At operation 540, the oxide layer is etched away, using any suitable etching process known to those of ordinary skill in the art, for example Inductively Coupled Plasma (ICP) etching with CF4 chemistry, in regions 506 and 507 (corresponding to lines A-A and B-B of FIG. 7, respectively). This will allow to perform the process of Deep Reactive Ion Etching (DRIE) to cut the chips with the desired shape out of the silicon substrate 502, at the end of the microfabrication procedure 500.

A bottom electrode layer comprising a bottom ground electrode section 508 and a bottom live electrode section 509 of the sensor Sᵢ is produced in operation 550 by depositing a 15 nm thick sub-layer of titanium forming an adhesion layer on the oxide layer 504 and, then, a 150 nm thick sub-layer of platinum as bottom electrodes. Both platinum and titanium sub-layers may be deposited in an electron beam evaporator or a sputtering chamber and annealed at 570° C. in nitrogen ambient. As can be seen in FIG. 6, the bottom live electrode section 509 is etched, using any suitable etching process known to those of ordinary skill in the art, in the bottom electrode layer (see area 509′), the rest of the bottom electrode layer forming the bottom ground electrode section 508. The bottom electrode layer may also be etched at locations 506 and 507, in preparation for operation 580, which is described hereinbelow. An example of bottom platinum electrode patterning process is the use of Lift Off Resist (LOR) as sacrificial layer underneath platinum in etching area, which prevent the platinum from adhering to the surface.

At operation 560, a piezoelectric layer 510, for example a PZT layer, having for example a 50 to 500 nm thickness, is deposited by the sol-gel method on the bottom electrode sections 508 and 509. The sol-gel method is a wet-chemical technique starting from a chemical solution (or sol) which acts as a precursor for an integrated network (or gel) of either discrete particles or network polymers, as described in more detail at http://en.wikipedia.orq/wiki/Sol-qel. The operation 560 may include a number of cyclic depositions, pyrolyzing and annealing operations to obtain a desired thickness of the piezoelectric layer 510. In this manner, for example, a good quality sol-gel derived Lead Zirconate Titanate (PZT) layer can be developed, free of cracks, by overcoming problems such as diffusion and oxidation of titanium and residual stresses in the platinum sub-layer. Of course, any other material capable of producing an electrical field as a result of compression may suitably replace PZT.

The sol-gel derived PZT layer 510 features an extremely large dielectric constant (in a range of 800-1100), an increased piezoelectric response and poling efficiency. To electrically connect the bottom electrode layer to a top electrode layer, which will be added later as described hereinafter, the PZT layer 510 is etched at circular areas 512 (see FIGS. 5 and 6). The PZT layer may also be etched, using any suitable etching process known to those of ordinary skill in the art, at locations 506 and 507, in preparation for operation 580, which is described hereinbelow. An example of PZT etch process is wet etching in DI:HCl:BOE 206:100:16 solution.

In a next operation 570, a top electrode layer comprising a top ground electrode section 514 and a top live electrode section 515 are produced by depositing a 15 nm thick sub-layer of titanium forming an adhesion layer on the PZT layer 510 and, then, a 150 nm thick sub-layer of platinum forming the top electrodes. During operation 570, the top electrode sections 514 and 515 connect with the bottom electrode sections 508 and 509, respectively through the etched areas 512 in the PZT layer 510. The same methods of deposition as employed for the bottom electrode section 508 and 509 may be used. As can be seen in FIG. 6, the top live electrode section 515 is etched in the top electrode layer (see combined areas 509′ and 515′), the rest of the top electrode layer forming the top ground electrode section 514. The top electrode layer may also be etched, using any suitable etching process known to those of ordinary skill in the art, at locations 506 and 507, in preparation for operation 580, which is described hereinbelow. As in the case of bottom platinum electrode patterning, a suitable top platinum electrode patterning process is the use of Lift Off Resist (LOR) as sacrificial layer underneath platinum in etching area, which prevent the platinum from adhering to the surface.

The overlapping geometry of the bottom electrode layer, piezoelectric layer and top electrode layer described hereinabove allows to easily create patterns on the various layers to define a sensor having an active area 513 and deactivate the rest of area on the surface of the substrate by shorting it without removing the piezoelectric material from the deactivated area on the substrate that may cause the delamination of the platinum bottom layer. Those of ordinary skill in the art will appreciate that operations of FIG. 5 may be used to define one or more sensors. In some embodiments, a plurality of sensors may be arranged in an array, depending on the created patterns of the various layers.

Then, at operation 580, the silicon substrate 502 may be etched using, for example DRIE, throughout at the regions 506 and 507 to extract a ring-shape chip comprising eight (8) sensors from the substrate. Finally, at operation 590, wires such as fine gold wires 518 and 519 are soldered at areas 512 to respective electrodes formed by electrode sections 508 and 514 and electrode sections 509 and 515.

FIG. 6 illustrates a top plan view and a cross sectional elevation view of a piezoelectric pressure sensor, produced using the method of FIG. 5. The bottom part of FIG. 6 corresponds to the lowest view of FIG. 5; only the wires 518 and 519 are not shown. It may be observed that the electrode formed by electrode sections 508 and 514 (and wire 518) forms a ground connection for the sensor while the electrode formed by electrode sections 509 and 515 (and wire 519) forms a live connection for the sensor, the active area 513 of the sensor being between the two connections. In the example of FIGS. 5 and 6, the active area 513 comprises a circular area of the bottom electrode section 508, a circular area of the piezoelectric layer 510 superposed to the circular area of the bottom electrode section 508 and a circular area of the top electrode section 515 superposed to the circular area of the piezoelectric layer 510.

The foregoing description refers to elements 508 and 514 as bottom and top ‘ground’ electrode sections, respectively, and to elements 509 and 515 as bottom and top ‘live’ electrode sections, respectively. In other realizations, elements 508 and 514 may form a live electrode while elements 509 and 515 may form a ground electrode. More generally, any connected pair of bottom and top electrode sections may act as a positive electrode, the other pair of bottom and top electrode sections acting as a negative electrode. It is understood that the terms ‘positive’ and ‘negative’ reflect relative voltages between complementary pairs of electrode sections.

The single ring-shaped array 300 comprising eight (8) piezoelectric sensors Sᵢ of FIG. 7 may be fabricated on a four (4) inch silicon substrate 502, which may accommodate the simultaneous fabrication of a plurality of arrays 300 of sensors Sᵢ, each fabricated using the method as described in relation to FIGS. 5 and 6 followed by etching the substrate from the back to extract the ring-shaped sensor arrays.

In operation, when installed in a sensed device such as a shock tube, each of the eight (8) piezoelectric pressure sensors reacts to a shock wave or mechanical wave pressure applied to the PZT layer 510 to produce an electric signal through the electrode formed by electrode sections 508 and 514 (and wire 518) and the electrode formed by electrode sections 509 and 515 (and wire 519). Electric signals obtained from the sensors may be amplified and are supplied to a signal analysis device. Signal analysis is based on a mathematical model, which may for example be based on Equations (1) and (2) when the pre-defined configuration of the sensor array is circular as shown for example in FIGS. 2 and 7, or based on Equations (5) and (6) when the pre-defined configuration of the sensor array is a cross as shown for example in FIG. 4.

FIG. 7 is a top plan view of a ring sensor array comprising eight (8) sensors. A ring-shaped array of eight (8) piezoelectric sensors Sᵢ should be mounted to a reliable support before it is exposed to wave pressure. The support also may also be used to establish electrical connections.

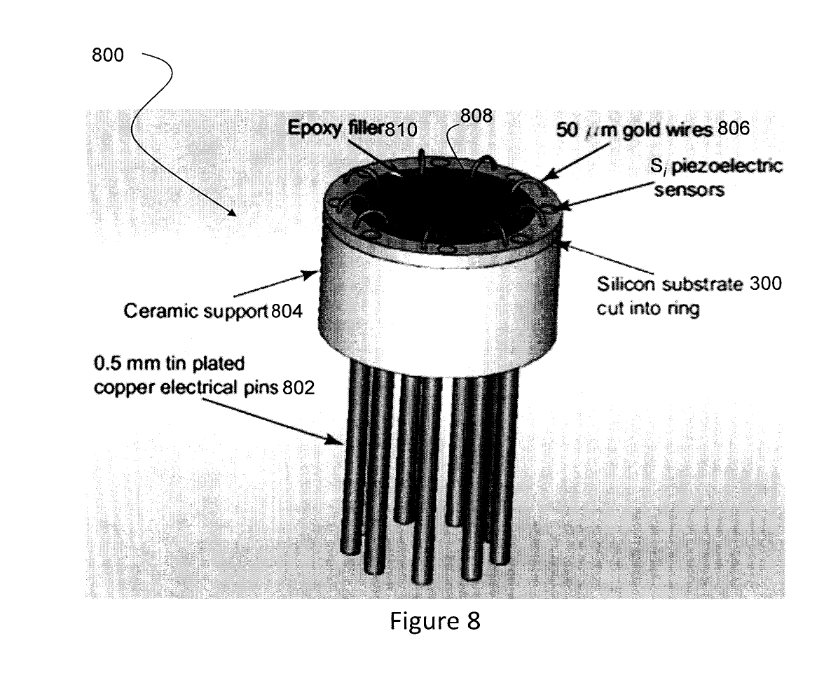

FIG. 8 is a perspective view of an example of packaging for supporting the ring-shaped array of eight (8) piezoelectric sensors of FIG. 7. Packaging 800 of FIG. 8 comprises, for example, a number of 0.5 mm tin plated copper electrical pins 802 extending through a cylindrical ceramic body 804 to form a device capable of being mounted on a printed circuit board (not shown). The ring-shaped array 300 of FIG. 7, which comprises eight (8) piezoelectric sensors Sᵢ fabricated on a silicon substrate 502 etched into an annular shape, is glued on a flat face of the ceramic body 804, opposite to the copper pins 802. Electrical connections (not shown) are established between the copper pins 802 and the electrodes of the eight (8) piezoelectric sensors Sᵢ of the ring-shaped array 300 of FIG. 7 through fine, for example 50 μm gold wires such as 806. Eight (8) of the gold wires 806 interconnect the electrodes of the eight (8) piezoelectric sensors Sᵢ formed by electrode sections 509 and 515 with corresponding ones of the copper pins 802. Another one of the gold wires 806 is used to interconnect a grounding copper pin 802 with the electrodes of the eight (8) piezoelectric sensors Sᵢ formed by the electrode sections 508 and 514. The electrical connections may be strengthened using conductive epoxy 808. Finally to obtain a flat surface, any void at the top of the ceramic body 804 where the ring-shaped array 300 is located is filled with a nonconductive epoxy filler 810.

A challenge in the microfabrication of these sensors is the elimination of the fine gold wires 518 and 519 from the design of FIG. 5 since topographies on the exposed surface of the sensor may affect the flow over the sensor.

Improving on this design involves wiring out the thin film piezoelectric structure on the front of substrate to the back side of the substrate while keeping the smooth and sealed surface of the sensors. A challenge in the microfabrication is thus to integrate the sensors' structures with electrical vias on a substrate. In fact there are some known approaches to create vias in silicon substrates. However, these approaches cannot be integrated with the thin film piezoelectric development procedure described above and a new approach for the compatible microfabrication of vias is presented.

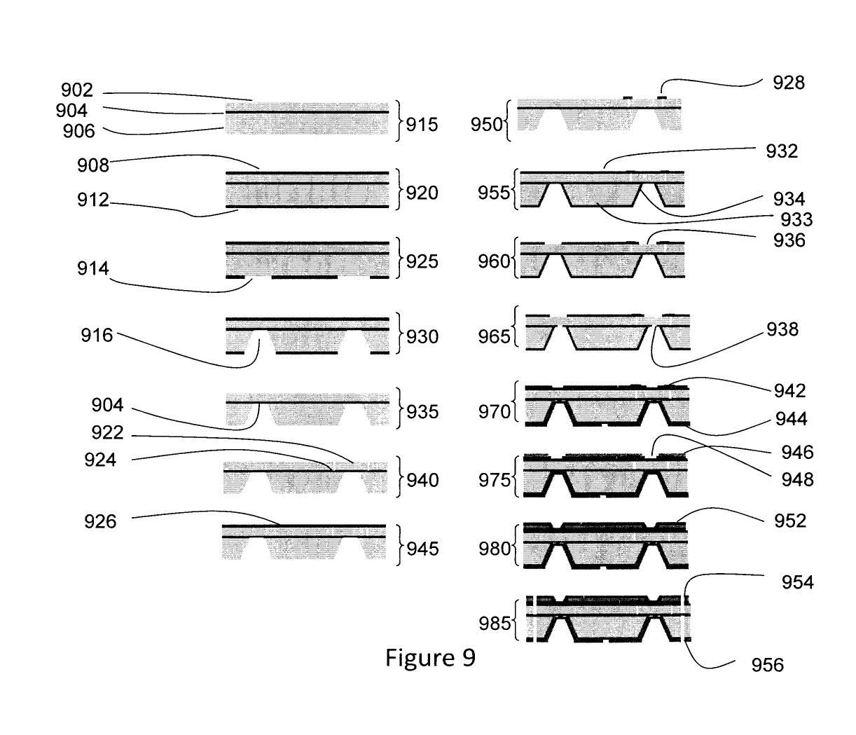

Therefore another example of a method of fabrication for the sensor Sᵢ delimited by the lines A-A and B-B of FIG. 7 will now be described with reference to FIG. 9, which shows a sequence of cross-sectional elevation views showing alternate examples of operations that may be used in the production of the sensor array for advanced packaging. In the description of FIG. 9, the various materials used as well as the dimensions defining layer thicknesses are for illustration purposes. Those of ordinary skill in the art will be able to adapt those materials and dimensions to the needs of particular applications.

Operation 915 starts with production of a Silicon On Insulator (SOI) substrate. The substrate has a 30 μm thick <100> silicon device layer 902, 2 μm thick Buried Oxide (BOX) layer 904 forming an upper electrical barrier, and 300 μm thick lower handle layer 906. These thicknesses are chosen to meet criteria such as mechanical strength, ease of silicon dry and wet etch that will be performed later on, enhanced electrical insulation and less capacitive parasites.

At operation 920, to make a reliable mask for the silicon wet etch, 7 μm thick Plasma Enhanced Chemical Vapor Deposited (PECVD) oxide layers 908 and 912 are respectively deposited on a front side and on a back side of the substrate. This will allow the substrate to withstand the long 300 μm silicon wet etch in potassium hydroxide (KOH) solution.

At operation 925 the oxide 912 on the lower handle layer 906 is etched 914 using Advanced Oxide Etching (AOE) and an ordinary photoresist mask to pattern the oxide mask. Proper care in executing this lithography process will prevent growing of any small flaw during wet etch, which could make the substrate unusable for the next steps.

During operation 930 the lower handle layer 906 is etched through to arrive at the BOX layer 904. The anisotropic etch of silicon in the KOH solution results in the formation of pits 916 in the lower handle layer 906 with inclined and smooth walls.

At operation 935, while protecting the BOX layer 904, the mask oxide layers 908 and 912 are on both sides are wet etched in hydrofluoric acid bath. To protect the BOX layer 904 in the bottom of the pits 916, the photoresist is spin coated on the lower handle layer 906 and wiped on the top surface, followed by plasma burning of the residues of photoresist. This is repeated for a few times until the bottoms of all the pits 916 are protected. Then the PECVD masks are removed in, for example hydrofluoric acid or any other suitable etching solution.

At operation 940, isolated islands 922 are created on the device layer 902 by Deep Reactive Ion Etching (DRIE) of annular trenches 924 down to the BOX layer 904. Since the surface of the sensors should not include any topography, these trenches should be closed with dielectric material. Therefore, the trenches should be as narrow as possible.

At operation 945 the trenches 924 are covered by deposition of 4 μm thick PECVD oxide 926 on the device layer 902. If the trenches are not completely covered, the processing materials in the next steps may enter into the trenches 924 and may short the isolated islands.

At operation 950, the PECVD oxide 926 is removed from the surface, using AOE, except at annular areas 928 over the trenches 924. The PECVD oxide 926 will later be replaced by thermal oxide except over the trenches 924.

At operation 955, the entire substrate is thermally oxidized to 1.5 μm oxide thickness after RCA (Radio Company of America) cleaning. This creates thermal oxide layers 932 and 933 by oxidizing both surfaces of the substrate as well as inclined walls 934 of the pits 916. This terminal oxide layer 933 becomes a lower electrical barrier. This process also increases the thickness of the BOX layer 904 in the pits 916.

At operation 960, the thermal oxide layer 932 is etched on isolated islands 936 using AOE to electrically reach to the device layer 902 from the front side of the substrate.

At operation 965, to electrically reach to the device layer 902 from the back side of the substrate, the BOX layer 904 is etched at annular areas 938, using AOE. Spray coated photolithography is used to deposit a uniform layer of photoresist (not shown) on the non-planar surface of the lower handle layer 906.

Bottom electrode sections of the sensors are realized by deposition of a layer 942 comprising 150 nm of platinum and 15 nm of titanium as an adhesion layer, at operation 970. This operation also includes the same metal deposition on the back side of the substrate, forming layer 944. The platinum layers 942 and 944 are deposited in an electron beam evaporator and annealed at 570° C. in nitrogen ambient.

At operation 975, a PZT layer 946 is deposited on the layer 942 by the sol-gel method. To electrically connect the top and bottom electrode sections, the PZT film is etched at the desired locations 948.

At operation 980, top electrode sections 952 are realized by deposition, on top of the PZT layer 946, of similar layers of platinum and titanium of the same thicknesses as in operation 970, these layers of platinum and titanium being etched at desired locations.

At operation 985, the device layer 902 is deep etched to the BOX layer 904 at annular area 954 followed by etching of the lower handle layer 906 to the BOX layer 904 are at annular area 956 to extract circular chips from the SOI substrate.

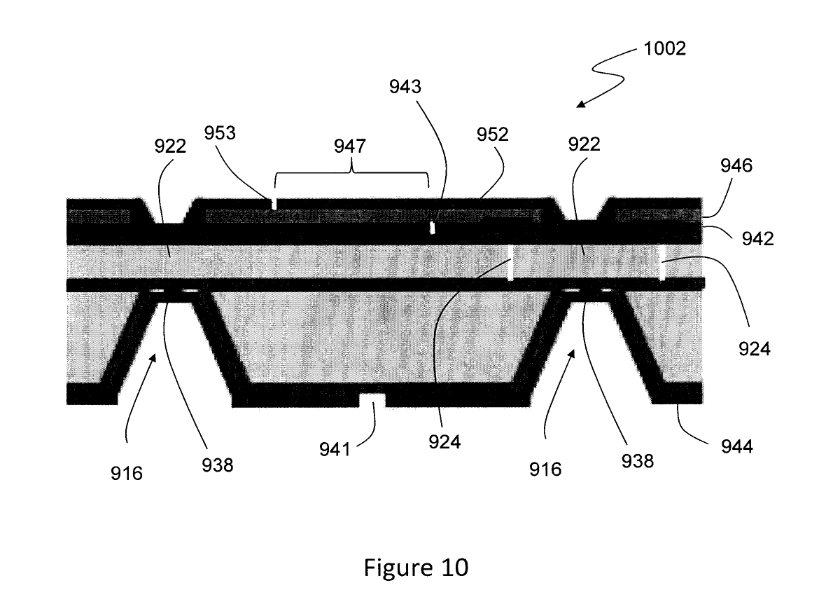

FIG. 10 is a close-up, cross-sectional elevation view of the sensor array produced using the operations of FIG. 9. A chip 1002 as shown is obtained following operation 985. Within the pits 916, platinum of the layer 944 fills the annular areas 938 in order to allow connection of the electrodes with a packaging shown in a later Figure. Trenches 941 etched into the layer 944 ensure isolation between the various connections provided at the various pits 916 so that, for example, a ground wire may be connected in the pit 916 on the left hand side of FIG. 10 and a live wire may be connected to in the pit 916 on the right hand side of FIG. 10. The platinum in the annular areas 938 connects to the bottom and top electrode sections 942 and 952 via the islands 922; the annular trenches 924 ensure isolation between neighboring connections within the device layer 902. The bottom electrode layer 942 is patterned by the etching of trenches 943 in appropriate locations. Likewise, the top electrode layer 952 is patterned by the etching of trenches 953 in appropriate locations. As shown at 947, pattern configurations of the bottom and top electrode layers 942 and 952 define an active area of the PZT layer 946, sandwiched between overlapping portions of a top electrode section 952 and of a bottom electrode section 942, forming a sensor.

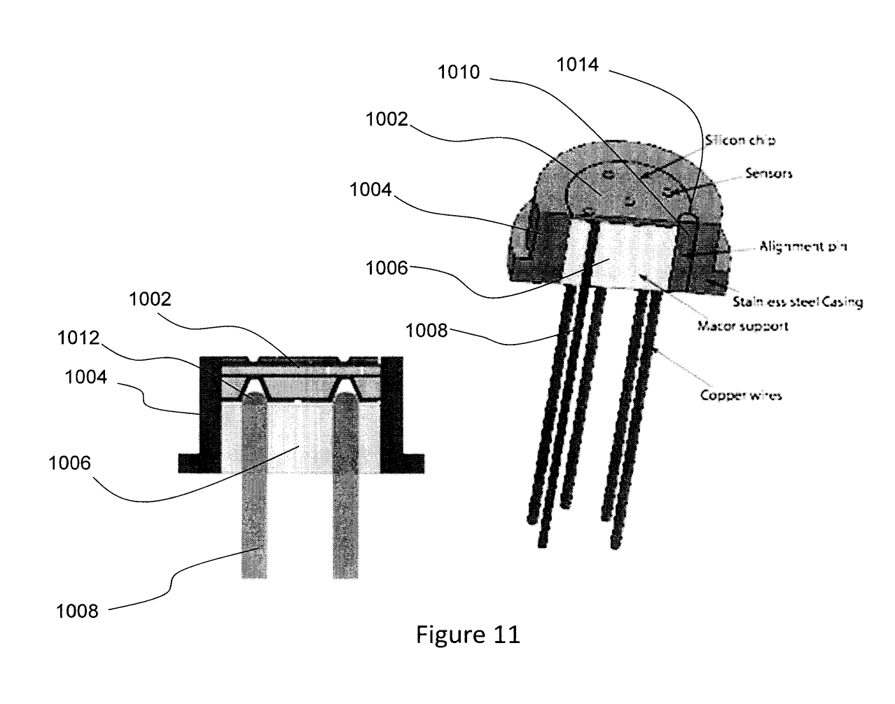

FIG. 11 is an example of a packaging method for the sensors arrays fabricated using the process shown in FIG. 9. In an embodiment, ease in packaging of the chip 1002 uses a circular chip with a semicircular notch 1014, for alignment purposes. An easy way to cut the substrate in this shape is using DRIE.

The chip 1002 will have a reliable support to be exposed to the fluid flow and to establish the electrical connections. Referring again to FIG. 11, the packaging comprises a stainless steel casing 1004 and a machinable ceramic (Macor) support 1006 as the main structure, 0.5 mm copper wires 1008 are used to establish electrical connections. Electrically conductive epoxy 1012 is used to attach the wires to the back side of the chip. An alignment pin 1010 is used to align the chip with the casing.

A method for measuring the amplitude, speed and direction of propagation of a wave in a fluid flow is described below.

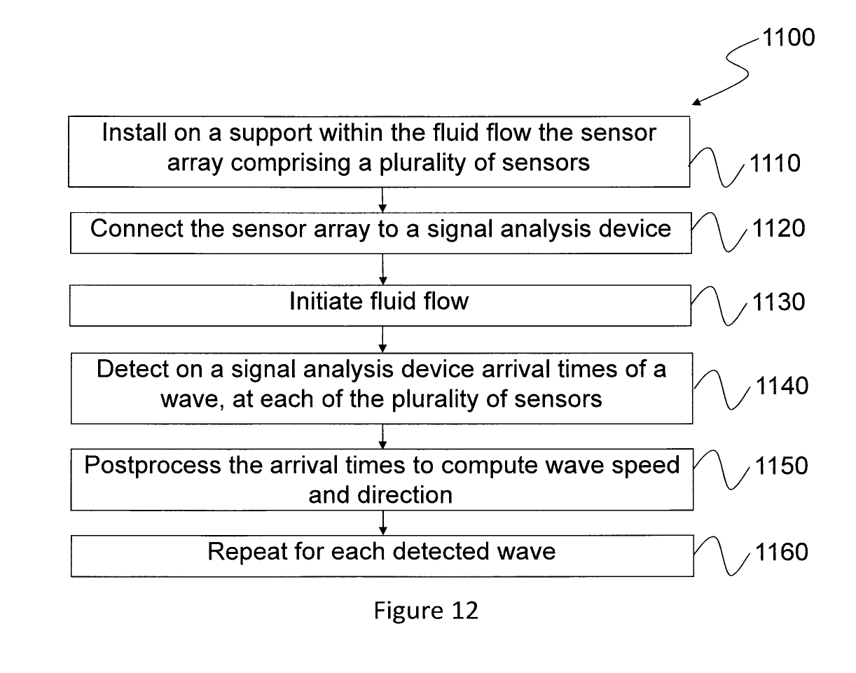

Measuring the speed and propagation direction of a wave in a fluid flow may be accomplished using a sensor array, for example the ring-shaped array 300 of eight (8) piezoelectric sensors Sᵢ of FIG. 7. FIG. 12 is a flow chart of examples of operations of a method of simultaneously measuring an amplitude time history, a speed and a direction of propagation of a shock wave or mechanical wave in flow. A method 1100 is initiated at operation 1110 after the sensor array has been installed at an appropriate location within the flow.

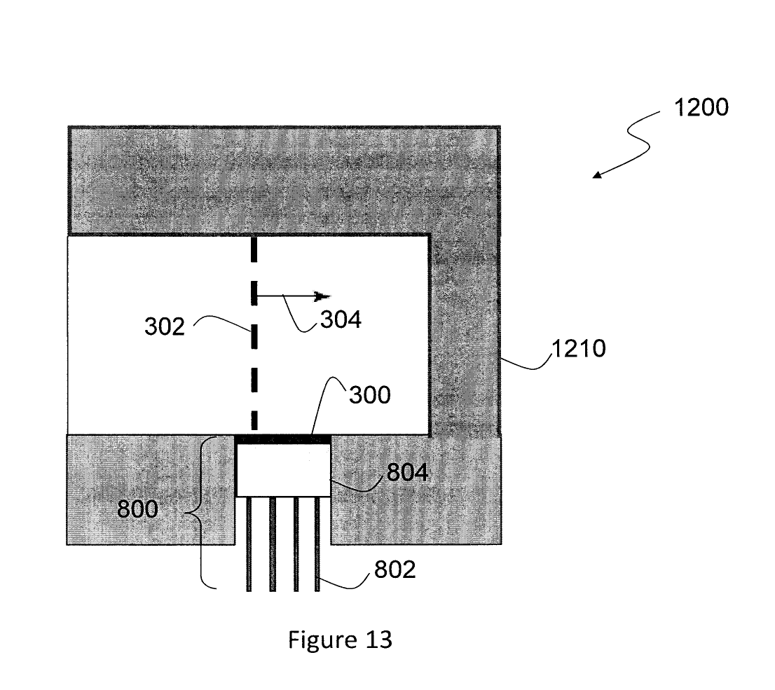

FIG. 13 is an elevation view of an example of set up for measuring the speed and direction of propagation of a wave, for example using the ring-shaped circular sensor array 300 of FIG. 7 in a shock tube. A set up 1200 comprises a shock tube 1210, and the packaging 800 including the ring-shaped circular sensor array 300, the ceramic body 804 and the copper pins 802. A relationship of the set up 1200 with the shock wave 302, introduced in the foregoing description of FIG. 3, and its direction 304 of propagation within the shock tube 1210 is shown in FIG. 13. As the shock wave 302 advances in the direction 304 along a length of the shock tube 1210, it passes over the various sensors Sᵢ (shown on earlier Figures) of the circular sensor array 300, at the top of the packaging 800. The shock wave 302 reaches the various sensors Sᵢ in rapid succession.

Returning to the description of FIG. 12, the eight (8) piezoelectric sensors Sᵢ of the ring-shaped array 300 are connected, at operation 1120, to a signal analysis device (not shown), which may for example comprise an oscilloscope having a recording mechanism. The flow, in the present example the shock wave 302, is initiated in the shock tube 1010 at operation 1130, and reaches the ring-shaped circular sensor array 300 as described hereinabove. At operation 1140, the signal analysis device detects an arrival time of each wave, here the shock wave 302, at each of the eight (8) piezoelectric sensors Sᵢ. Postprocessing of the arrival times on the sensors, as processed by the signal analysis device, provides the speed and direction 304 of propagation of the wave, here the shock wave 302, using the formulas (1) and (2) and the analysis procedure shown in relation to the foregoing description of FIG. 3, at operation 1150. Finally, the operations 1140 and 1150 are successively is repeated for each detected wave, in operation 1160.

Additionally to their capacity to transform a mechanical signal into electrical impulses as sensors or receivers, piezoelectric materials can also produce mechanical waves if electrically excited appropriately, as emitters. Accordingly, the sensors arranged and/or fabricated as described in the present disclosure may also individually be operated as emitters. Individually tailoring the wave signal simultaneously produced by each emitter in an emitter array, operating as a phased array, then allows control over the features of the mechanical wave beam produced by the emitter array. Furthermore, the sensors may successively be used as emitters, to produce for example an ultrasound beam of short duration, known as a pulse, in the medium into which they are in contact, and then shortly thereafter as receivers to analyze an echo produced by the reflection and refraction of this pulse with various inhomogeneities in the medium. Operating individual sensors and sensor arrays in this pulse-echo mode would, for example, allow for the detection of defects in the medium or imaging the various features in the medium, as it is already done in ultrasound non-destructive testing (NDT) and imaging. So the sensors and sensor arrays described here may be used for NDT and imaging, with new capabilities owing to their small size.

It is to be understood that the present disclosure is not limited in its application to the details of construction and parts illustrated in the accompanying drawings and described hereinabove. The present disclosure is capable of other embodiments and of being practiced in various ways. It is also to be understood that the phraseology or terminology used herein is for the purpose of description and not limitation. Hence, although the present disclosure has been described hereinabove by way of illustrative embodiments thereof, it may be modified, without departing from the spirit, scope and nature of the subject disclosure.

What is claimed is:

1. A method of manufacturing a piezoelectric sensor, comprising:
forming an electrical barrier on top of a silicon substrate;
depositing, on top of the electrical barrier, a bottom electrode layer defining a bottom positive electrode section and a bottom negative electrode section;
depositing, on top of the bottom electrode layer, a piezoelectric layer;
etching, through the piezoelectric layer, a positive electrode connection area and a negative electrode connection area;
depositing on top of the piezoelectric layer, a top electrode layer, the top electrode layer making contact with the bottom electrode layer through the positive and negative electrode connection areas and defining a upper positive electrode section and a upper negative electrode section;
whereby a sensing area is created, in the piezoelectric layer, in an area of overlap between the upper positive electrode section and the bottom negative electrode section or between the upper negative electrode section and the bottom positive electrode section.

2. The method of claim 1, wherein the piezoelectric layer comprises a lead zirconate titanate (PZT) layer deposited using a sol-gel process.

3. The method of claim 1, wherein the electrical barrier is an oxide layer.

4. The method of claim 1, wherein the bottom electrode layer comprises a platinum sub-layer on top of a titanium sub-layer, the titanium sub-layer forming an adhesion layer.

5. The method of claim 1, wherein the top and bottom electrode layers are patterned to deactivate a remainder of the piezoelectric layer.

6. The method of claim 1, comprising:
forming patterns on the top and bottom electrode layers to define a plurality of sensors arranged in an array.

7. A piezoelectric sensor comprising:
a silicon substrate;
an electrical barrier on top of the silicon substrate;
a bottom electrode layer, on top of the electrical barrier, the bottom electrode layer defining a bottom positive electrode section and a bottom negative electrode section;
a piezoelectric layer, on top of the bottom electrode layer, the piezoelectric layer defining a positive electrode connection area and a negative electrode connection area; and
a top electrode layer, on top of the piezoelectric layer, the top electrode layer making contact with the bottom electrode layer through the positive and negative electrode connection areas and defining a upper positive electrode section and a upper negative electrode section;
wherein a sensing area is defined, in the piezoelectric layer, in an area of overlap between the upper positive electrode section and the bottom negative electrode section or between the upper negative electrode section and the bottom positive electrode section.

8. The sensor of claim 7, wherein the piezoelectric layer comprises a lead zirconate titanate (PZT) layer deposited using a sol-gel process.

9. The sensor of claim 7, wherein the electrical barrier is an oxide layer.

10. The sensor of claim 7, wherein the bottom electrode layer comprises a platinum sub-layer on top of a titanium sub-layers, the titanium sub-layer forming an adhesion layer.

11. A piezoelectric sensor array having a plurality of piezoelectric sensors as defined in claim 7.

12. The piezoelectric sensor array of claim 11, mounted on a shock tube for detecting a speed and a direction of propagation of a shock wave in the shock tube.

13. The piezoelectric sensor array of claim 11, wherein the piezoelectric sensors are disposed in a circular configuration to form a circular array.

14. The piezoelectric sensor array of claim 11, wherein the piezoelectric sensors are disposed in a cross-shaped configuration to form a cross-shaped array.

15. A method of measuring an amplitude, a speed and a direction of propagation of a shock wave in a shock tube, comprising:
attaching to the shock tube a piezoelectric sensor array comprising a plurality of piezoelectric sensors disposed in a pre-defined configuration;
connecting the piezoelectric sensor array to a signal analysis device;
initiating the shock wave in the shock tube; and
detecting on the signal analysis device an arrival time of the shock wave at each of the plurality of piezoelectric sensors.

16. The method of claim 15, wherein the pre-defined configuration is circular.

17. The method of claim 16, wherein:
the shock wave is initiated at a distance h_{c} from a center of the sensor array, each of the sensors is at a distance R from the center of the sensor array, θ is an angle between a direction of wave propagation in the shock tube and a reference direction of the sensor array, φᵢ is an angle between each sensor Sᵢ and the reference direction, a distance hᵢ between the shock wave and each sensor Sᵢ being according to:
hᵢ=h_{c}−R cos(φᵢ−θ); and
an arrival time tᵢ of the shock wave, at each of the plurality of sensors, being according to:
$${t}_{i} = {t}_{c} - \frac{R}{{u}_{s}} cos ( {Φ}_{i} - Θ ) ;$$
wherein t_{c} is an arrival time of the shock wave at the center of the array and μₛ is the speed of the shock wave.

18. The method of claim 17, further comprising postprocessing at the signal analysis device the arrival time of the shock wave at each of the plurality of sensors.

19. A smart pressure sensor array comprising:
a plurality of sensors packaged in close proximity in the sensor array; and
one or more wired connections for connecting the sensors to a data acquisition system;
whereby the sensor array provides the data acquisition system with pressure time histories at an individual location of each sensor of the array.

20. The method of claim 1, comprising:
providing a lower handle layer;
providing an isolating layer on top of the lower handle layer;
providing the silicon substrate on top of the isolating layer;
forming trenches in the silicon substrate for forming silicon islands;
forming, in the electrical barrier, voids for connection with each silicon islands so that the bottom electrode layer reaches the silicon islands through the voids of the electrical barrier;
etching the lower handle layer, from a face opposite the top electrode layer, to form pits, each pit reaching an island of the silicon substrate;
forming a lower electrical barrier in the pits and on the face of the lower handle layer opposite the top electrode layer; and
depositing, on the lower handle layer, a conductive layer reaching the silicon substrate through the pits, the conductive layer having trenches for isolating each pit from other pits.

21. A method of initiating a mechanical wave in a medium, comprising:
placing the sensor of claim 7 in contact with the medium;
connecting the sensor to an electrical signal source; and
initiating the mechanical wave in the medium by imparting an electrical impulse signal from the signal source on the sensor.

22. The method of claim 21, comprising:
connecting the sensor to a signal analysis device; and
measuring on the signal analysis device features of the mechanical wave echoing back to the sensor.

23. A method of initiating mechanical waves in a medium, comprising:
attaching to the medium the piezoelectric sensor array of claim 11, the plurality of piezoelectric sensors being disposed in a pre-defined configuration;
connecting the piezoelectric sensor array to an electrical signal source; and
initiating mechanical waves in the medium by imparting an electrical impulse signal from the signal source on the piezoelectric sensor array.

24. The method of claim 23, comprising:
connecting the piezoelectric sensor array to a signal analysis device; and
measuring on the signal analysis device features of the mechanical waves echoing back to the piezoelectric sensor array.
